(19) United States
(12) Patent Application Publication
(10) Pub. No.: US 2026/0221986 A1
(43) Pub. Date: Jul. 30, 2026

(54) COMPRESSING DATASET USING MACHINE LEARNING MODELS

(71) Applicant: International Business Machines Corporation, Armonk, NY (US)

(72) Inventors: Shivaram Subramanian, Frisco, TX (US); Wei Sun, Scarsdale, NY (US); Markus Ettl, Yorktown Heights, NY (US); Zhengliang Xue, Yorktown Heights, NY (US)

(21) Appl. No.: 19/041,184

(22) Filed: Jan. 30, 2025

(51) Int. Cl. H03M 7/30

(52) U.S. Cl. CPC H03M 7/6011; H03M 7/3071; H03M 7/3077

(57) ABSTRACT

A computer-implemented method for generating a compressed dataset. A processor set trains a first machine learning model using a dataset. The first machine learning model is trained to generate probabilities of predictions based on a number of features extracted from columns in the dataset. The processor set ranks the number of features based on a feature attribution analysis for the number of features. The feature attribution analysis determines contribution of each feature from the number of features to predictions made by the first machine learning model. The processor set expands a feature vector using a number of top ranked features from the number of features for generating the compressed dataset. The compressed dataset comprises a number of data entries from the dataset that is associated with the number of top ranked features from the number of features.

### BACKGROUND

The disclosure relates generally to compressing datasets using machine learning models.

Data compression is a process of reducing the size of data by encoding data using fewer bits while retaining essential information from data. Data compression can be used for data transmission. Data compression can mainly be categorized into two main types such as lossless compression and lossy compression. Lossless compression ensures that the original data can be perfectly reconstructed from the compressed form, making lossless compression ideal for text files, program files, and databases. On the other hand, lossy compression sacrifices some fidelity for higher compression rates, often used in multimedia applications such as images, videos, and audio files.

Data compression plays a vital role in various stages of machine learning. Data compression in machine learning involves reducing the size of dataset while preserving critical information needed for model training and inference. As datasets grow in size due to the increasing availability of high-dimensional data such as images, videos, and sensor data, efficient storage and processing of datasets becomes paramount. In this case, compression of datasets enables users to store and manage large datasets without incurring excessive costs in storage and processing resources.

### SUMMARY

According to one illustrative embodiment, a computer-implemented method for generating a compressed dataset is provided. A processor set trains a first machine learning model using a dataset. The first machine learning model is trained to generate probabilities of predictions based on a number of features extracted from columns in the dataset. The processor set ranks the number of features based on a feature attribution analysis for the number of features. The feature attribution analysis determines contribution of each feature from the number of features to predictions made by the first machine learning model. The processor set expands a feature vector using a number of top ranked features from the number of features for generating the compressed dataset. The compressed dataset comprises a number of data entries associated with the number of top ranked features from the number of features. According to other illustrative embodiments, a computer system, and a computer program product for generating a compressed dataset are provided.

### BRIEF DESCRIPTION OF THE DRAWINGS

FIG. 1 is a pictorial representation of a computing environment in which illustrative embodiments may be implemented;

FIG. 2 is an illustration of a block diagram of a data management environment in accordance with an illustrative embodiment;

FIG. 3 is an illustration of a decision tree in accordance with an illustrative embodiment;

FIG. 4 is a flowchart of a process for generating a compressed dataset in accordance with an illustrative embodiment;

FIG. 5 is a flowchart of a process for merging rows in the dataset in accordance with an illustrative embodiment;

FIG. 6 is a flowchart of a process for incrementally merging rows in the compressed dataset in accordance with an illustrative embodiment;

FIG. 7 is a flowchart of a process for inputting data to generate a decision to solve an optimization problem in accordance with an illustrative embodiment;

FIG. 8 is a flowchart of a process for incrementally merging rows in the compressed dataset in accordance with an illustrative embodiment; and

FIG. 9 is a block diagram of a data processing system in accordance with an illustrative embodiment.

### DETAILED DESCRIPTION

A computer implemented method generates a compressed dataset. A processor set trains a first machine learning model using a dataset. The first machine learning model is trained to generate probabilities of predictions based on a number of features extracted from columns in the dataset. The processor set ranks the number of features based on a feature attribution analysis for the number of features. The feature attribution analysis determines contribution of each feature from the number of features to predictions made by the first machine learning model. The processor set expands a feature vector using a number of top ranked features from the number of features for generating the compressed dataset. The compressed dataset comprises a number of data entries from the dataset that is associated with the number of top ranked features from the number of features. As a result, the illustrative embodiments provide a technical effect of generating a compressed dataset that is representative of the original dataset by including and tracking top ranked features that contribute most to predictions made using the original dataset.

In the illustrative embodiments, as part of expanding a feature vector to generate the compressed dataset using a number of data entries from the dataset, the processor set selects a first top ranked feature from the number of features based on ranking for the number of features. The feature vector is expanded using the top ranked feature. The processor set identifies a number of rows from the dataset. The number of rows is identified based on column associated with the first top ranked feature. The processor set merges the number of rows into single row in the dataset to generate the compressed dataset. As a result, the illustrative embodiments provide a technical effect of reducing the size of dataset by merging rows that include values for a number of top ranked features in the dataset that include the first top ranked feature.

In the illustrative embodiments, the processor set generates an output using a second machine learning model for solving an optimization problems based on the compressed dataset. The processor set performs a convergence analysis to determine quality of the compressed dataset based on the output. The processor set determines whether the quality of the compressed dataset exceeds a pre-defined threshold. In response to determining that the quality of the compressed dataset does not exceed the pre-defined threshold, the processor set compresses the compressed dataset by incrementally merging rows in the compressed dataset based on the number of top ranked features until the quality of the compressed dataset exceeds the pre-defined threshold. As a result, the illustrative embodiments provide a technical effect of reducing the size of the dataset to an optimal level by incrementally or iteratively merging rows that include values for a number of top ranked features in the dataset.

In the illustrative embodiments, the processor set inputs the compressed dataset to the second machine learning model for making a decision to solve an optimization problem. As a result, the illustrative embodiments provide a technical effect of using the compressed data to efficiently solve an optimization problem.

In the illustrative embodiments, as part of compressing the compressed dataset by incrementally merging rows in the compressed dataset based on the number of top ranked features until the quality of the compressed dataset exceeds the pre-defined threshold, the processor set selects a second top ranked feature from the number of features based on ranking for the number of features. The feature vector is expanded using the second top ranked feature that is ranked immediately after the first top ranked feature. The processor set identifies a number of second rows from the compressed dataset. The number of second rows is identified based on columns associated with the first top ranked feature and the second top ranked feature. The processor set merges the number of second rows into single row in the compressed dataset to update the compressed dataset. As a result, the illustrative embodiments provide a technical effect of further reducing size of dataset by merging rows that include values for a number of top ranked features in the dataset that include the first top ranked feature and the second top ranked feature.

In the illustrative embodiments, the convergence analysis is performed using Mixed Integer Programming (MIP). As a result, the illustrative embodiments provide a technical effect of providing a robust framework for convergence analysis, particularly when both continuous and discrete variables are involved.

In the illustrative embodiments, the number of features is ranked using Shapley Additive exPlanations (SHAP) scores associated with the number of features. As a result, the illustrative embodiments provide a technical effect of providing an efficient algorithm that ensures fair and consistent allocation of feature importance when ranking the number of features.

A computer system comprises a processor set, a set of one or more computer-readable storage media, and program instructions, stored in the set of one or more computer-readable storage media, to cause the processor set to perform the following computer operations. A processor set trains a first machine learning model using a dataset. The first machine learning model is trained to generate probabilities of predictions based on a number of features extracted from columns in the dataset. The processor set ranks the number of features based on a feature attribution analysis for the number of features. The feature attribution analysis determines contribution of each feature from the number of features to predictions made by the first machine learning model. The processor set expands a feature vector using a number of top ranked features from the number of features for generating the compressed dataset. The compressed dataset comprises a number of data entries from the dataset that is associated with the number of top ranked features from the number of features. As a result, the illustrative embodiments provide a technical effect of generating a compressed dataset that is representative of original dataset by including and tracking top ranked features that contribute most to predictions made using the original dataset.

In the illustrative embodiments, as part of expanding a feature vector to generate the compressed dataset using a number of data entries from the dataset, the processor set further executes the program instructions to select a first top ranked feature from the number of features based on ranking for the number of features. The feature vector is expanded using the top ranked feature. The processor set further executes the program instructions to identify a number of rows from the dataset. The number of rows is identified based on column associated with the first top ranked feature. The processor set further executes the program instructions to merge the number of rows into single row in the dataset to generate the compressed dataset. As a result, the illustrative embodiments provide a technical effect of reducing size of dataset by merging rows that include values for a number of top ranked features in the dataset that include the first top ranked feature.

In the illustrative embodiments, the processor set further executes the program instructions to generate an output using a second machine learning model for solving an optimization problem based on the compressed dataset. The processor set further executes the program instructions to perform a convergence analysis to determine quality of the compressed dataset based on the output. The processor set further executes the program instructions to determine whether the quality of the compressed dataset exceeds a pre-defined threshold. In response to determining that the quality of the compressed dataset does not exceed the pre-defined threshold, the processor set further executes the program instructions to compress the compressed dataset by incrementally merging rows in the compressed dataset based on the number of top ranked features until the quality of the compressed dataset exceeds the pre-defined threshold. As a result, the illustrative embodiments provide a technical effect of reducing the size of the dataset to an optimal level by incrementally or iteratively merging rows that include values for a number of top ranked features in the dataset.

In the illustrative embodiments, the processor set further executes the program instructions to input the compressed dataset to the second machine learning model for making a decision to solve an optimization problem. As a result, the illustrative embodiments provide a technical effect of using the compressed data to efficiently solve an optimization problem.

In the illustrative embodiments, as part of compressing the compressed dataset by incrementally merging rows in the compressed dataset based on the number of top ranked features until the quality of the compressed dataset exceeds the pre-defined threshold, the processor set further executes the program instructions to select a second top ranked feature from the number of features based on ranking for the number of features. The feature vector is expanded using the second top ranked feature that is ranked immediately after the first top ranked feature. The processor set further executes the program instructions to identify a number of second rows from the compressed dataset. The number of second rows is identified based on columns associated with the first top ranked feature and the second top ranked feature. The processor set further executes the program instructions to merge the number of second rows into single row in the compressed dataset to update the compressed dataset. As a result, the illustrative embodiments provide a technical effect of further reducing the size of the dataset by merging rows that include values for a number of top ranked features in the dataset that include the first top ranked feature and the second top ranked feature.

In the illustrative embodiments, the convergence analysis is performed using Mixed Integer Programming (MIP). As a result, the illustrative embodiments provide a technical effect of providing a robust framework for convergence analysis, particularly when both continuous and discrete variables are involved.

In the illustrative embodiments, the number of features is ranked using Shapley Additive exPlanations (SHAP) scores associated with the number of features. As a result, the illustrative embodiments provide a technical effect of providing an efficient algorithm that ensures fair and consistent allocation of feature importance when ranking the number of features.

In the illustrative embodiments, a computer program product generates a compressed dataset. The computer program product comprises a set of one or more computer-readable storage media and program instructions, stored in the set of one or more computer-readable storage media, for causing a processor set to perform the following computer operations. The program instructions are executable by a computer system to train a first machine learning model using a dataset. The first machine learning model is trained to generate probabilities of predictions based on a number of features extracted from columns in the dataset. The program instructions are executable by the computer system to rank the number of features based on a feature attribution analysis for the number of features. The feature attribution analysis determines contribution of each feature from the number of features to predictions made by the first machine learning model. The program instructions are executable by the computer system to expand a feature vector using a number of top ranked features from the number of features for generating the compressed dataset. The compressed dataset comprises a number of data entries from the dataset that is associated with the number of top ranked features from the number of features. As a result, the illustrative embodiments provide a technical effect of generating a compressed dataset that is representative of original dataset by including and tracking top ranked features that contribute most to predictions made using the original dataset.

In the illustrative embodiments, as part of expanding a feature vector to generate the compressed dataset using a number of data entries from the dataset, the program instructions are further executable by the computer system to select a first top ranked feature from the number of features based on ranking for the number of features. The feature vector is expanded using the top ranked feature. The program instructions are further executable by the computer system to identify a number of rows from the dataset. The number of rows is identified based on column associated with the first top ranked feature. The program instructions are further executable by the computer system to merge the number of rows into single row in the dataset to generate the compressed dataset. As a result, the illustrative embodiments provide a technical effect of reducing size of the dataset by merging rows that include values for a number of top ranked features in the dataset that include the first top ranked feature.

In the illustrative embodiments, the program instructions are further executable by the computer system to generate an output using a second machine learning model for solving an optimization problem based on the compressed dataset. The program instructions are further executable by the computer system to perform a convergence analysis to determine quality of the compressed dataset based on the output. The program instructions are further executable by the computer system to determine whether the quality of the compressed dataset exceeds a pre-defined threshold. In response to determining that the quality of the compressed dataset does not exceed the pre-defined threshold, the program instructions are further executable by the computer system to compress the compressed dataset by incrementally merging rows in the compressed dataset based on the number of top ranked features until the quality of the compressed dataset exceeds the pre-defined threshold. As a result, the illustrative embodiments provide a technical effect of reducing the size of the dataset to an optimal level by incrementally or iteratively merging rows that include values for a number of top ranked features in the dataset.

In the illustrative embodiments, the program instructions are further executable by the computer system to input the compressed dataset to the second machine learning model for making a decision to solve an optimization problem. As a result, the illustrative embodiments provide a technical effect of using the compressed data to efficiently solve an optimization problem.

In the illustrative embodiments, as part of compressing the compressed dataset by incrementally merging rows in the compressed dataset based on the number of top ranked features until the quality of the compressed dataset exceeds the pre-defined threshold, the program instructions are further executable by the computer system to select a second top ranked feature from the number of features based on ranking for the number of features. The feature vector is expanded using the second top ranked feature that is ranked immediately after the first top ranked feature. The program instructions are further executable by the computer system to identify a number of second rows from the compressed dataset. The number of second rows is identified based on columns associated with the first top ranked feature and the second top ranked feature. The program instructions are further executable by the computer system to merge the number of second rows into single row in the compressed dataset to update the compressed dataset. As a result, the illustrative embodiments provide a technical effect of further reducing the size of the dataset by merging rows that include values for a number of top ranked features in the dataset that include the first top ranked feature and the second top ranked feature.

In the illustrative embodiments, the number of features is ranked using Shapley Additive exPlanations (SHAP) scores associated with the number of features. As a result, the illustrative embodiments provide a technical effect of providing an efficient algorithm that ensures fair and consistent allocation of feature importance when ranking the number of features.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment ("CPP embodiment" or “CPP”) is a term used in the present disclosure to describe any set of one or more storage media (also called "mediums") collectively included in a set of one or more storage devices that collectively include machine readable code corresponding to instructions and/or data for performing computer operations specified in a given CPP claim. A "storage device" is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation, or garbage collection, but this does not render the storage device as transitory because the data is not transitory while it is stored.

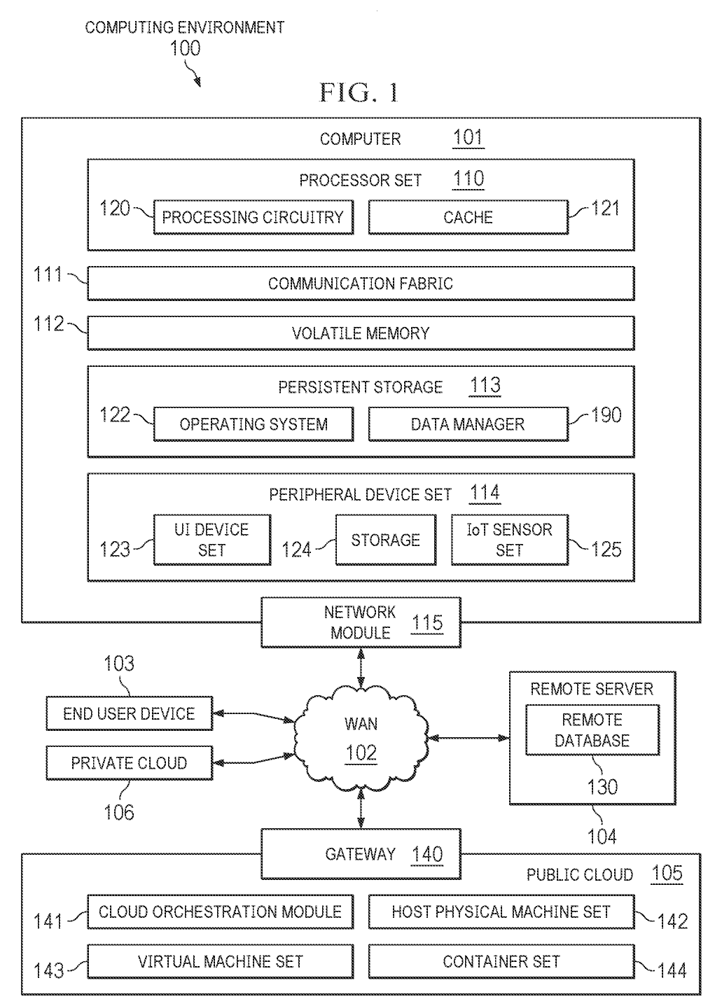

With reference now to the figures, and in particular with reference to FIG. 1, a block diagram of a computing environment is depicted in accordance with an illustrative embodiment. Computing environment 100 contains an example of an environment for the execution of at least some of the computer code involved in performing the inventive methods, such as data manager 190. In addition to data manager 190, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and data manager 190, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network, or querying a database such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one or more computer processors of any type now known or to be developed in the future. Processing circuitry 120 may be distributed over multiple packages, for example, multiple coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions and associated data are accessed by processor set 110 to control and direct performance of the inventive methods. In computing environment 100, at least some of the instructions for performing the inventive methods may be stored in data manager 190 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input / output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, volatile memory 112 is located in a single package and is internal to computer 101, but, alternatively or additionally, volatile memory 112 may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data, and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in data manager 190 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers, and edge servers.

END USER DEVICE (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as a thin client, heavy client, mainframe computer, desktop computer, and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data application portability between the multiple constituent clouds. In this embodiment, public cloud 105 and private cloud 106 are both part of a larger hybrid cloud.

CLOUD COMPUTING SERVICES AND/OR MICROSERVICES: Public cloud 105 and private cloud 106 are programmed and configured to deliver cloud computing services and/or microservices (not separately shown in FIG. 1). Unless otherwise indicated, the word “microservices” shall be interpreted as inclusive of larger “services” regardless of size. Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider’s systems, and back. In some embodiments, cloud services may be configured and orchestrated according to an “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

The illustrative embodiments recognize and take into account one or more different considerations as described herein. For example, the illustrative embodiments recognize and take into account that existing prescriptive artificial intelligence (AI) that leverages multiple large language models and memory is slow in response time.

The illustrative embodiments also recognize and take into account that prescriptive AI needs to generate a response consistent with a query in a quick manner in some situations. In addition, the illustrative embodiments also recognize and take into account that modern machine learning models, particularly deep learning networks, can be computationally expensive and memory-intensive. In this case, data compression can lower energy consumption, as well as accelerating data transfer, inferencing, and loading time.

Thus, illustrative embodiments of the present invention provide a computer implemented method, computer system, and computer program product for generating a compressed dataset. A processor set trains a first machine learning model using a dataset. The first machine learning model is trained to generate probabilities of predictions based on a number of features extracted from columns in the dataset. The processor set ranks the number of features based on a feature attribution analysis for the number of features. The feature attribution analysis determines contribution of each feature from the number of features to predictions made by the first machine learning model. The processor set expands a feature vector using a number of top ranked features from the number of features for generating the compressed dataset. The compressed dataset comprises a number of data entries associated with the number of top ranked features from the number of features.

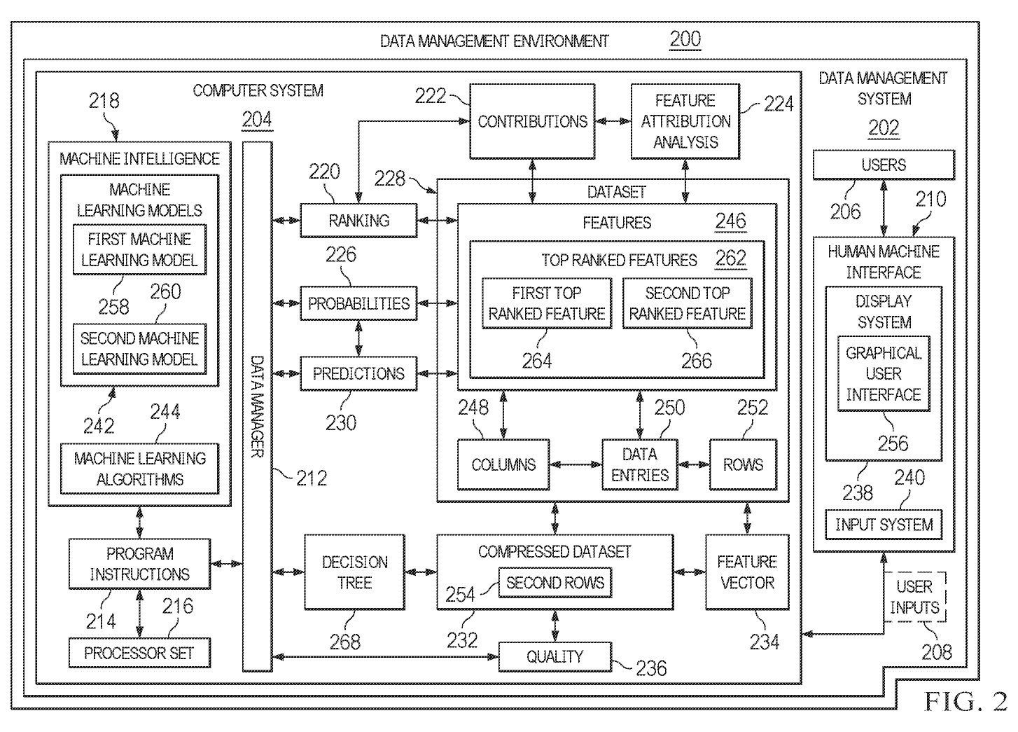

With reference now to FIG. 2, an illustration of a block diagram of a data management environment is depicted in accordance with an illustrative embodiment. In this illustrative example, data management environment 200 includes components that can be implemented in hardware such as the hardware shown in computing environment 100 in FIG. 1.

In this illustrative example, data management system 202 in data management environment 200 can be used for managing dataset 228 to generate compressed dataset 232 in computer system 204. In this illustrative example, dataset 228 can include data obtained from a plurality of data sources. For example, dataset 228 can include domain-specific data over a time period, where the domain-specific data can be used for generating rules for decision making. In this illustrative example, data management system 202 includes computer system 204 which includes data manager 212. Data manager 212 is located in computer system 204. Data manager 212 may be implemented using data manager 190 in FIG. 1.

Data manager 212 can be implemented in software, hardware, firmware, or a combination thereof. When software is used, the operations performed by data manager 212 can be implemented in program instructions configured to run on hardware, such as a processor unit. When firmware is used, the operations performed by data manager 212 can be implemented in program instructions and data and stored in persistent memory to run on a processor unit. When hardware is employed, the hardware can include circuits that operate to perform the operations in data manager 212.

In the illustrative examples, the hardware can take a form selected from at least one of a circuit system, an integrated circuit, an application specific integrated circuit (ASIC), a programmable logic device, or some other suitable type of hardware configured to perform a number of operations. With a programmable logic device, the device can be configured to perform the number of operations. The device can be reconfigured at a later time or can be permanently configured to perform the number of operations. Programmable logic devices include, for example, a programmable logic array, a programmable array logic, a field programmable logic array, a field programmable gate array, and other suitable hardware devices. Additionally, the processes can be implemented in organic components integrated with inorganic components and can be comprised entirely of organic components excluding a human being. For example, the processes can be implemented as circuits in organic semiconductors.

As used herein, “a number of” when used with reference to items, means one or more items. For example, “a number of operations” is one or more operations.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C,” may include item A, item A and item B, or item B. This example also may include item A, item B, and item C, or item B and item C. Of course, any combination of these items can be present. In some illustrative examples, “at least one of” can be, for example, without limitation, two of item A; one of item B; and ten of item C; four of item B and seven of item C; or other suitable combinations.

Computer system 204 is a physical hardware system and includes one or more data processing systems. When more than one data processing system is present in computer system 204, those data processing systems are in communication with each other using a communications medium. The communications medium can be a network. The data processing systems can be selected from at least one of a computer, a server computer, a tablet computer, or some other suitable data processing system.

As depicted, computer system 204 includes processor set 216 that is capable of executing program instructions 214 implementing processes in the illustrative examples. In other words, program instructions 214 are computer-readable program instructions.

As used herein, a processor unit in processor set 216 is a hardware device and is comprised of hardware circuits such as those on an integrated circuit that respond to and process instructions and program code that operate a computer. A processor unit can be implemented using processor set 110 in FIG. 1. When processor set 216 executes program instructions 214 for a process, processor set 216 can be one or more processor units that are in the same computer or in different computers. In other words, the process can be distributed between processor set 216 on the same or different computers in computer system 204.

Further, processor set 216 can be of the same type or different types of processor units. For example, processor set 216 can be selected from at least one of a single core processor, a dual-core processor, a multi-processor core, a general-purpose central processing unit (CPU), a graphics processing unit (GPU), a digital signal processor (DSP), or some other type of processor unit.

As depicted, computer system 204 includes machine intelligence 218. Machine intelligence 218 can include machine learning models 242 and machine learning algorithms 244. Machine learning models 242 is a branch of artificial intelligence (AI) that enables computers to detect patterns and improve performance without direct programming commands. Rather than relying on direct input commands to complete a task, machine learning models 242 relies on input data. The data is fed into the machine, one of machine learning algorithms 244 is selected, parameters for the data are configured, and the machine is instructed to find patterns in the input data through optimization algorithms. The data model formed from analyzing the data is then used to predict future values.

Machine intelligence 218 is continuously refined over time through trial and error. Equivalence of assets or products can be effectively performed by supervised machine learning, unsupervised machine learning, or semi-supervised machine learning so that products or assets that do not match descriptively can nevertheless be matched. Over time, the data model from machine learning can provide a greater degree of flexibility in matching machine intelligence 218.

Machine intelligence 218 can be implemented using one or more systems such as an artificial intelligence system, a neural network, a generative neural network, a Bayesian network, an expert system, a fuzzy logic system, a genetic algorithm, or other suitable types of systems. Machine learning models 242 and machine learning algorithms 244 may make computer system 204 a special purpose computer for reducing size of datasets such that resource management and allocation for computer system 204 can be improved.

Machine learning models 242 involves using machine learning algorithms 244 to build computation models based on samples of data. The samples of data used for training are referred to as training data or training datasets. Machine intelligence 218 can make predictions without being explicitly programmed to make these predictions. Machine intelligence 218 can be used for training and retraining computation models for a number of different types of applications. These applications include, for example, medicine, financial services, healthcare, speech recognition, computer vision, or other types of applications. In this illustrative example, machine learning models 242 include first machine learning model 258 and second machine learning model 260. First machine learning model 258 and second machine learning model 260 work together to process dataset 228 to generate compressed dataset 232.

In this illustrative example, first machine learning model 258 and second machine learning model 260 can work together to process dataset 228 to generate compressed dataset 232 in a number of ways. For example, first machine learning model 258 can be a predictive model that solves a prediction task either generically by training a neural network or training a tree ensemble such as gradient-boosted trees with domain-specific data such as data associated with airline ticket pricing or grocery pricing. On the other hand, second machine learning model 260 can be a prescriptive model that generates an optimal prescriptive decision tree using outputs from first machine learning model 258. In this illustrative example, the optimal prescriptive decision tree serves as a decision policy since the optimal prescriptive decision tree prescribes a specific action for every possible context.

In this illustrative example, machine learning algorithms 244 can include supervised machine learning algorithms, semi-supervised machine learning algorithms, and unsupervised machine learning algorithms. Supervised machine learning can train machine learning models using data containing both the inputs and desired outputs. Examples of machine learning algorithms include gradient-boosting algorithms, neural networks, XGBoost, K-means clustering, and Random Forest algorithms.

In this illustrative example, machine learning models 242 can be retrained or updated using new data or outputs generated by machine learning models 242 such that parameters in machine learning algorithms selected for machine learning models 242 can be adjusted to improve accuracy and efficiency of machine learning models 242.

In this illustrative example, data manager 212 uses dataset 228 for training first machine learning model 258. As depicted, dataset 228 can include domain-specific data such as data associated with airline ticket pricing or grocery pricing, financial data, or any suitable data from a business domain. In this illustrative example, first machine learning model 258 is trained as a predictive model that can be used for generating predictions 230 and probabilities 226 for dataset 228 based on a number of features 246 extracted from columns 248 in dataset 228. In this illustrative example, each column in dataset 228 corresponds to a particular attribute or variable associated with a record represented by a row in dataset 228. In other words, the number of features 246 are attributes and variables associated with information from rows in dataset 228.

In this illustrative example, first machine learning model 258 is trained to understand the relationships between the number of features 246 and target variables for outcomes represented by predictions 230 made by first machine learning model 258. In addition, first machine learning model 258 can generate probabilities 226 associated with predictions 230. For example, if dataset 228 includes grocery pricing, predictions 230 can include price predictions of a customer to buy a particular product, and probabilities 226 can include probabilities of the customer to buy the particular product at the predicted price.

In this illustrative example, data manager 212 can rank the number of features 246 based on feature attribution analysis 224 for the number of features 246. Feature attribution analysis 224 is a technique used to understand and interpret how individual features in the number of features 246 contribute to the predictions 230 made by first machine learning model 258. For example, feature attribution analysis 224 can rank the number of features 246 using Shapley Additive exPlanations (SHAP) scores for the number of features 246. As a result, data manager 212 generates ranking 220 for the number of features 246 based on contributions 222 for features 246 based on feature attribution analysis 224.

In this illustrative example, data manager 212 identifies a number of top ranked features 262 from features 246 based on ranking 220. The number of top ranked features 262 are features that contribute most to predictions 230 made by first machine learning model 258. In this illustrative example, data manager 212 can identify a number of data entries 250 from dataset 228 for generating compressed dataset 232 based on the number of top ranked features 262. In other words, compressed dataset 232 includes the number of data entries 250 that are associated with the number of top ranked features 262 from the number of features 246. In addition, data manager 212 can expand feature vector 234 using the number of top ranked features 262 to keep track of the number of top ranked features 262.

In this illustrative example, compressed dataset 232 can be generated in a number of ways. For example, data manager 212 can select first top ranked feature 264 from the number of top ranked features 262 based on ranking 220. In this example, first top ranked feature 264 is a feature that ranks first in the number of top ranked features 262 and feature vector 234 is expanded using first top ranked feature 264. Subsequently, data manager 212 can identify a number of rows 252 from dataset 228 based on columns in columns 248 that are associated with first top ranked feature 264. In other words, rows 252 are rows that have same value in column that correspond to first top ranked feature 264. As a result, rows with same value in column that correspond to first top ranked feature 264 are merged into one single row to generate compressed dataset 232.

For example, if dataset 228 includes airplane ticket pricing data, first top ranked feature 264 can be a feature that represents “advance purchase window”, which can be further categorized into “0 days”, “7 days”, “14 days”, and “more than 21 days”. In this example, data manager 212 merges rows that have values from “0” to “7” in column “advance purchase window” into a single row. In a similar fashion, data manager 212 merges rows that have values from “7” to “14” in column “advance purchase window” into a single row, rows that have values from “14” to “21” in column “advance purchase window” into a single row, and rows that have values greater than “21” in column “advance purchase window” into a single row.

In addition, data manager 212 can determine quality 236 of compressed dataset 232 using second machine learning model 260. As depicted, second machine learning model 260 can be a prescriptive model that generates optimal prescriptive decision trees for solving optimization problems. In this illustrative example, data manager 212 uses second machine learning model 260 to generate an output for solving an optimization problem based on compressed dataset 232. For example, if compressed dataset 232 includes data associated with airline ticket pricing, the objective for second machine learning model 260 is to maximize total predicted revenue summed over all data samples, which varies based on prices for the airline tickets. In this example, second machine learning model 260 can use optimization techniques such as column generation to generate outputs.

In this illustrative example, data manager 212 can determine quality 236 of compressed dataset 232 in a number of ways. For example, data manager 212 can perform a convergence analysis based on the output generated by second machine learning model 260 using compressed dataset 232. In this illustrative example, convergence analysis examines how performance metrics such as accuracy, loss, or error rates for second machine learning model 260 as compressed dataset 232 changes. In this example, data manager 212 can perform the convergence analysis using mixed integer programming (MIP).

Subsequently, data manager 212 compares quality 236 for compressed dataset 232 to a pre-defined threshold to determine if quality 236 exceeds the pre-defined threshold. In this example, compressed dataset 232 has good quality and can be used for further processing if quality 236 exceeds the pre-defined threshold. On the other hand, data manager 212 can further improve quality 236 for compressed dataset 232 if quality 236 does not exceed the pre-defined threshold. For example, data manager 212 can further improve compressed dataset 232 by incrementally merging rows in compressed dataset 232 based on the number of top ranked features 262 until quality 236 of the compressed dataset 232 exceeds the pre-defined threshold.

In this illustrative example, data manager 212 can further select second top ranked feature 266 from the number of top ranked features 262 based on ranking 220. In this example, second top ranked feature 266 is a feature that ranks immediately after first top ranked feature 264 in the number of top ranked features 262 and feature vector 234 is expanded using second top ranked feature 266. Subsequently, data manager 212 can identify a number of second rows 254 from compressed dataset 232 based on columns in compressed dataset 232 that are associated with first top ranked feature 264 and second top ranked feature 266. In other words, the number of second rows 254 are rows that have same value in columns that correspond to first top ranked feature 264 and second top ranked feature 266. As a result, rows with same value in columns that correspond to first top ranked feature 264 and second top ranked feature 266 are merged into one singe row to update compressed dataset 232.

For example, compressed dataset 232 can include airplane ticket pricing data and first top ranked feature 264 can be a feature that represents “advance purchase window”, which can be further categorized into “0 days”, “7 days”, “14 days”, and “more than 21 days”, while second top ranked feature 266 is feature that represent “one way trip”, which can be further categorized into “true” and “false”. In this example, data manager 212 merges rows in compressed dataset 232 that have values from “0” to “7” in column “advance purchase window” and value of “true” in column “one way trip” into a single row. In addition, data manager 212 merges rows in compressed dataset 232 that have values from “0” to “7” in column “advance purchase window” and value of “false” in column “one way trip” into a single row. In a similar fashion, data manager 212 merges rows in compressed dataset 232 that have values from “7” to “14” in column “advance purchase window” and “true” in column “one way trip” into a single row. Further, data manager 212 merges rows in compressed dataset 232 that have values from “7” to “14” in column “advance purchase window” and “false” in column “one way trip” into a single row.

In a similar fashion, data manager 212 merges rows in compressed dataset 232 that have values from “14” to “21” in column “advance purchase window” and “true” in column “one way trip” into a single row. In addition, data manager 212 merges rows in compressed dataset 232 that have values from “14” to “21” in column “advance purchase window” and “false” in column “one way trip” into a single row. Finally, data manager 212 merges rows in compressed dataset 232 that have values greater than “21” in column “advance purchase window” and “true” in column “one way trip” into a single row. In addition, data manager 212 merges rows in compressed dataset 232 that have values greater than “21” in column “advance purchase window” and “false” in column “one way trip” into a single row. As a result, compressed dataset 232 is updated based on first top ranked feature 264 and second top ranked feature 266. In other words, feature vector 234 is gradually or incrementally widened based on ranking 220 for features 246.

In this illustrative example, data manager 212 can repeat the steps of determining quality 236 and comparing quality 236 for compressed dataset 232 to the pre-defined threshold to determine if quality 236 exceeds the pre-defined threshold. In one illustrative example, quality 236 exceeds the pre-defined threshold if the MIP gap from convergence analysis does not change beyond the pre-defined threshold as more features from the number of top ranked features 262 are selected. In this example, the MIP gap is a measure used in optimization analysis to indicate how close the output generated by second machine learning model 260 using compressed dataset 232 is to the optimal solution. In other words, quality 236 for compressed dataset 232 exceeds the pre-defined threshold if selecting more features from the number of top ranked features 262 does not improve compressed dataset 232 anymore. In other words, quality 236 for compressed dataset 232 exceeds the pre-defined threshold when the upper bound and achieved objective for convergence analysis converges. In this illustrative example, since the most influential features are considered first, a good solution is quickly converged even when the original feature space of prescriptive rules for dataset 228 is large.

On the other hand, data manager 212 can repeat the method described above to further incrementally improve compressed dataset 232 based on third top ranked feature, the third top ranked feature and fourth top ranked feature, or any number of top ranked features from the number of top ranked features 262 until quality 236 exceeds the pre-defined threshold.

Subsequently, data manager 212 can input compressed dataset 232 to second machine learning model 260 after quality 236 exceeds the pre-defined threshold. In this example, decision tree 268 can be generated based on compressed dataset 232 for making a decision to solve an optimization problem.

It should be understood that compressed dataset 232 can also be used for other purposes. For example, compressed dataset 232 can be used for training a prescriptive model such as second machine learning model 260 for solving optimization problems using other input data.

In this illustrative example, users 206 can interact with computer system 204 through user inputs to computer system 204. In this illustrative example, user inputs 208 can be generated by users 206 using human machine interface (HMI) 210. As depicted, human machine interface 210 includes display system 238 and input system 240. Display system 238 is a physical hardware system and includes one or more display devices on which graphical user interface 256 can be displayed. The display devices can include at least one of a light emitting diode (LED) display, an organic light emitting diode (OLED) display, a computer monitor, a projector, a flat panel display, a heads-up display (HUD), a head-mounted display (HMD), smart glasses, augmented reality glasses, or some other suitable device that can output information for the visual presentation of information.

In this example, users 206 are people that can interact with graphical user interface 256 through user inputs 208 generated by input system 240. Input system 240 is a physical hardware system and can be selected from at least one of a mouse, a keyboard, a touch pad, a trackball, a touchscreen, a stylus, a motion sensing input device, a gesture detection device, a data glove, a cyber glove, a haptic feedback device, or some other suitable type of input device. For example, users 206 can view dataset 228, top ranked features 262, ranking 220, contributions 222, compressed dataset 232, feature vector 234, and decision tree 268 through graphical user interface 256.

In one illustrative example, one or more solutions are present that overcome a problem with managing temporary spaces in a computer system. As a result, one or more technical solutions may provide an ability to increase the efficiency and performance in computer system 204 by incrementally reducing size of dataset to generate compressed dataset and size of machine learning model using the compressed dataset.

In the illustrative example, computer system 204 can be configured to perform at least one of the steps, operations, or actions described in the different illustrative examples using software, hardware, firmware, or a combination thereof. As a result, computer system 204 operates as a special purpose computer system in which data manager 212 in computer system 204 enables compressing of datasets such that the resulted compressed data can improve the functioning of computer system 204 when processed. In particular, data manager 212 transforms computer system 204 into a special purpose computer system as compared to currently available general computer systems that do not have data manager 212.

In the illustrative example, the use of data manager 212 in computer system 204 integrates processes into a practical application for incrementally compressing datasets. In other words, data manager 212 in computer system 204 is directed to a practical application of processes integrated into data manager 212 in computer system 204 that supports compressing of datasets. In this illustrative example, data manager 212 can efficiently help computer system 204 to increase computer performance and avoid wasting computing resources because efficient management and utilization of compressed datasets in a computer system provide significant technical advantages compared to uncompressed datasets.

The illustration of data management environment 200 in FIG. 2 is not meant to imply physical or architectural limitations to the manner in which an illustrative embodiment can be implemented. Other components in addition to or in place of the ones illustrated may be used. Some components may be unnecessary. Also, the blocks are presented to illustrate some functional components. One or more of these blocks may be combined, divided, or combined and divided into different blocks when implemented in an illustrative embodiment. For example, the outputs from second machine learning model 260 can be organized in data structures other than decision trees. For example, the outputs from second machine learning model 260 can be presented using arrays, matrices, or any suitable data structure.

It should also be understood that feature vector 234 can also be expanded by features from the number of features 246 that are selected primarily by the requirement of tasks. In other words, feature vector 234 can also be expanded by features selected based on conditions in addition to SHAP scores. However, the features selected for expanding feature vector 234 must satisfy validity and interpretability. For example, the features selected for expanding feature vector 234 need to satisfy all industry and specific contractual regulations, the features can be linked to the decision such as decisions from the original observational data as opposed to being abstracted features such as neural-network generated embeddings, and features with high influence scores.

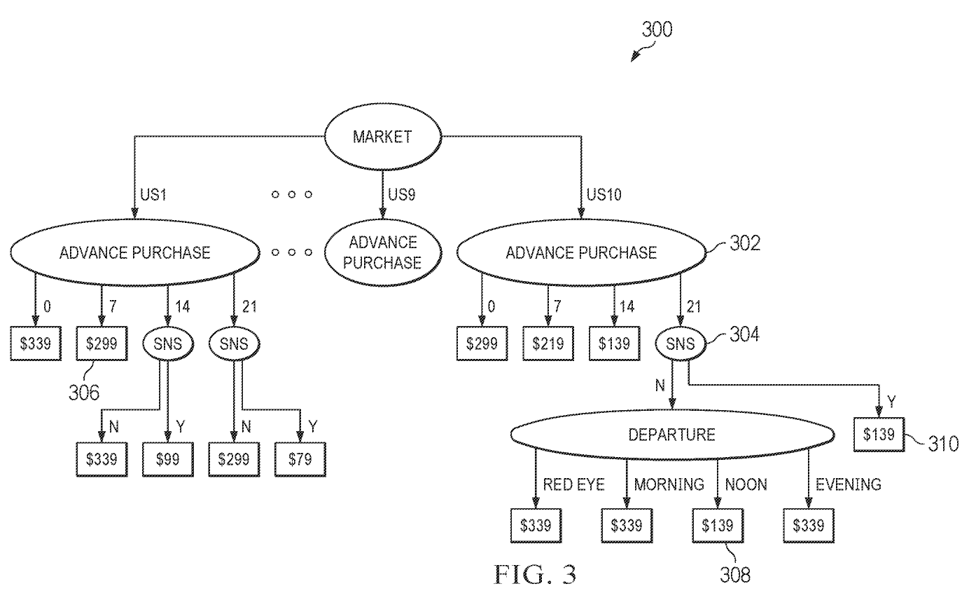

With reference now to FIG. 3, an illustration of a decision tree is shown in accordance with an illustrative embodiment. In this illustrative example, decision tree 300 can be an example of decision tree 268 generated by second machine learning model 260 in FIG. 2.

Decision tree 300 represents a number of rules for airline ticket pricing. In this illustrative example, the input for generating decision tree 300 can be a dataset that includes a number of features associated with airline pricing. For example, the dataset can include “one way vs. round trip”, “day of week”, “market”, “advance purchase”, Saturday-night stay” (SNS), or any feature that can influence airline ticket pricing. In this illustrative example, decision tree 300 includes a number of internal nodes, leaf nodes, and branches. Each internal node in decision tree 300 represents a feature that influences pricing for airline ticket. For example, internal node 302 represents a feature of pricing rules for advance purchase tickets in market “US10”, and internal node 304 represents a feature of pricing rules for airline tickets associated with “Saturday-night stay” (SNS), where customers are required to spend Saturday night at the destination.

Further, branches in decision tree 300 represent possible outcomes or choices resulting from feature of pricing rules for each internal node. For example, branches under internal node 302 represent four possible outcomes resulting from feature “advance purchase”, which include booking airline tickets in market “US10” 0 days, 7 days, 14 days, or 21 days before departure. In another example, branches under internal node 304 represent two possible outcomes resulting from feature “Saturday-night stay” (SNS), which include simple binary results. In addition, each leaf node in decision tree 300 represents a final decision, predictions, or outcomes. For example, leaf node 306 represents the final outcomes of an airline ticket pricing rule for advance purchase of ticket 7 days before the departure date in market of “US1”. In another example, leaf node 310 represent that the final outcomes of an airline ticket pricing rule for advance purchase of a ticket 21 days before the departure date with “Saturday-night stay” (SNS) in market “US10”. In yet another example, leaf node 308 represents the final outcomes of an airline ticket pricing rule for advance purchase of a ticket 21 days before the departure date without “Saturday-night stay” (SNS) and a departure time of “noon” in market “US10”. In this illustrative example, a final outcome represented by leaf nodes such as leaf node 306, leaf node 308, and leaf node 310 are examples of predictions made by second machine learning model 260 in FIG. 2.

The illustration of decision tree 300 in FIG. 3 is not meant to imply physical or architectural limitations to the manner in which an illustrative embodiment can be implemented. Other components in addition to or in place of the ones illustrated may be used. Some components may be unnecessary. Also, the blocks are presented to illustrate some functional components. One or more of these blocks may be combined, divided, or combined and divided into different blocks when implemented in an illustrative embodiment. For example, decision tree 300 can represent outcomes and policy rules for applications in other technical fields such as financial services. It should also be understood that the policy rules presented by decision tree 300 can be organized in other types of data structures such as arrays or matrices.

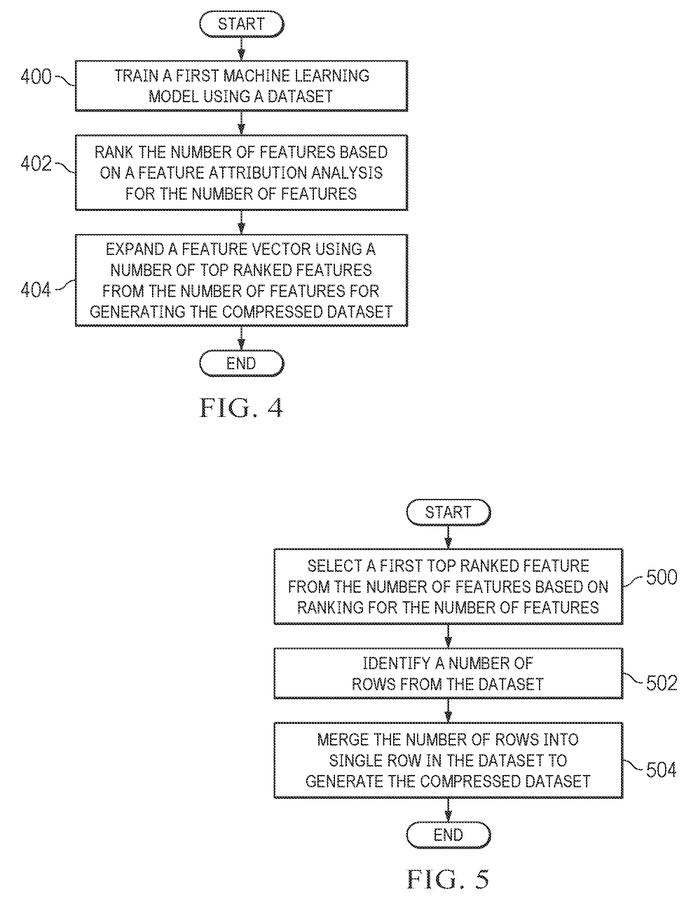

With reference now to FIG. 4, a flowchart illustrating a process for generating a compressed dataset is shown in accordance with an illustrative embodiment. The process in FIG. 4 can be implemented in hardware, software, or both. When implemented in software, the process can take the form of program instructions that are run by one of more processor units located in one or more hardware devices in one or more computer systems. For example, the process can be implemented in data manager 212 in computer system 204 in FIG. 2.

The process begins by training a first machine learning model using a dataset. (step 400). The first machine learning model is trained to generate probabilities of predictions based on a number of features extracted from columns in the dataset. The process ranks the number of features based on a feature attribution analysis for the number of features (step 402). The feature attribution analysis determines contribution of each feature from the number of features to predictions made by the first machine learning model. The process expands a feature vector using a number of top ranked features from the number of features for generating the compressed dataset (step 404). The compressed dataset comprises a number of data entries from the dataset that is associated with the number of top ranked features from the number of features. The process terminates thereafter.

With reference now to FIG. 5, a flowchart illustrating a process for merging rows in the dataset is shown in accordance with an illustrative embodiment. The process in this flowchart is an example of an implementation for step 404 in FIG. 4.

The process begins by selecting a first top ranked feature from the number of features based on ranking for the number of features (step 500). In this step, the feature vector is expanded using the top ranked feature. The process identifies a number of rows from the dataset (step 502). In step 502, the number of rows is identified based on column associated with the first top ranked feature. The process merges the number of rows into single row in the dataset to generate the compressed dataset (step 504). The process terminates thereafter.

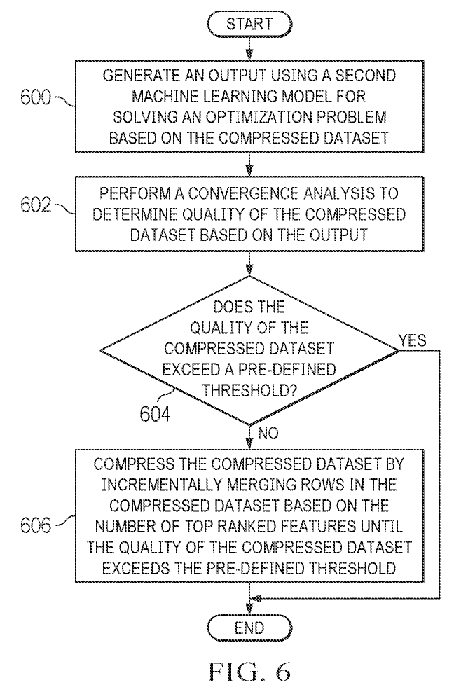

With reference now to FIG. 6, a flowchart illustrating a process for incrementally merging rows in the compressed dataset is shown in accordance with an illustrative embodiment. The process in this figure is an example of an additional step that can be performed with the steps in FIG. 5.

The process begins by generating an output using a second machine learning model for solving an optimization problem based on the compressed dataset (step 600). The process performs a convergence analysis to determine quality of the compressed dataset based on the output (Step 602). The process determines whether the quality of the compressed dataset exceeds a pre-defined threshold (step 604). If the quality of the compressed dataset exceeds a pre-defined threshold, the process terminates thereafter.

With reference again to step 604, if the quality of the compressed dataset does not exceed a pre-defined threshold, the process compresses the compressed dataset by incrementally merging rows in the compressed dataset based on the number of top ranked features until the quality of the compressed dataset exceeds the pre-defined threshold (step 606). The process terminates thereafter.

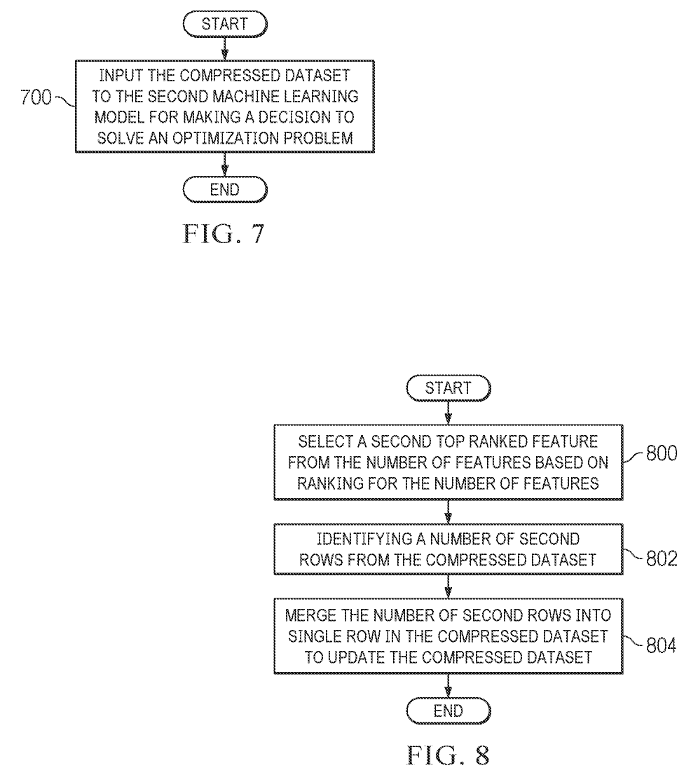

With reference now to FIG. 7, a flowchart illustrating a process for inputting data to generate a decision to solve an optimization problem is shown in accordance with an illustrative embodiment. The process in this figure is an example of an additional step that can be performed with the steps in FIG. 6.

The process begins by inputting the compressed dataset to the second machine learning model for making a decision to solve an optimization problem (step 700). The process terminates thereafter.

With reference now to FIG. 8, a flowchart illustrating a process for incrementally merging rows in the compressed dataset is shown in accordance with an illustrative embodiment. The process in this flowchart is an example of an implementation for step 606 in FIG. 6.

The process begins by selecting a second top ranked feature from the number of features based on ranking for the number of features (step 800). In step 800, the feature vector is expanded using the second top ranked feature that is ranked immediately after the first top ranked feature.

The process identifies a number of second rows from the compressed dataset (Step 802). In step 802, the number of second rows is identified based on columns associated with the first top ranked feature and the second top ranked feature. The process merges the number of second rows into single row in the compressed dataset to update the compressed dataset (step 804). The process terminates thereafter.

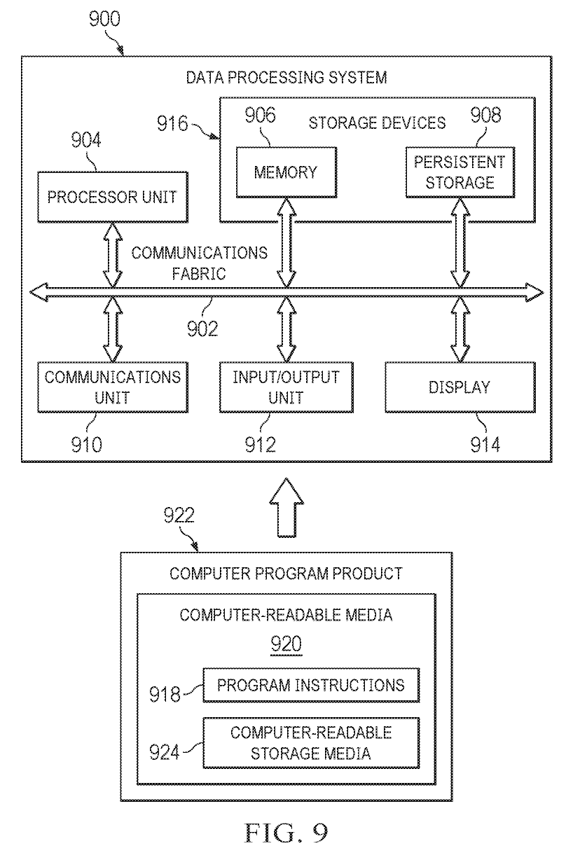

Turning now to FIG. 9, a block diagram of a data processing system is depicted in accordance with an illustrative embodiment. Data processing system 900 can be used to implement computers and computing devices in computing environment 100 in FIG. 1. Data processing system 900 can also be used to implement computer system 204 in FIG. 2. In this illustrative example, data processing system 900 includes communications framework 902, which provides communications between processor unit 904, memory 906, persistent storage 908, communications unit 9 10, input/output (I/O) unit 9 12, and display 914. In this example, communications framework 902 takes the form of a bus system.

Processor unit 904 serves to execute instructions for software that can be loaded into memory 906. Processor unit 9 04 includes one or more processors. For example, processor unit 904 can be selected from at least one of a multicore processor, a central processing unit (CPU), a graphics processing unit (GPU), a physics processing unit (PPU), a digital signal processor (DSP), a network processor, or some other suitable type of processor. Further, processor unit 904 can be implemented using one or more heterogeneous processor systems in which a main processor is present with secondary processors on a single chip. As another illustrative example, processor unit 904 can be a symmetric multi-processor system containing multiple processors of the same type on a single chip.

Memory 906 and persistent storage 908 are examples of storage devices 916. A storage device is any piece of hardware that is capable of storing information, such as, for example, without limitation, at least one of data, program instructions in functional form, or other suitable information either on a temporary basis, a permanent basis, or both on a temporary basis and a permanent basis. Storage devices 9 16 may also be referred to as computer-readable storage devices in these illustrative examples. Memory 9 06, in these examples, can be, for example, a random-access memory or any other suitable volatile or non-volatile storage device. Persistent storage 908 may take various forms, depending on the particular implementation.

For example, persistent storage 908 may contain one or more components or devices. For example, persistent storage 908 can be a hard drive, a solid-state drive (SSD), a flash memory, a rewritable optical disk, a rewritable magnetic tape, or some combination of the above. The media used by persistent storage 908 also can be removable. For example, a removable hard drive can be used for persistent storage 908.

Communications unit 910, in these illustrative examples, provides for communications with other data processing systems or devices. In these illustrative examples, communications unit 910 is a network interface card.

Input/output unit 912 allows for input and output of data with other devices that can be connected to data processing system 900. For example, input/output unit 912 may provide a connection for user input through at least one of a keyboard, a mouse, or some other suitable input device. Further, input/output unit 912 may send output to a printer. Display 9 14 provides a mechanism to display information to a user.

Instructions for at least one of the operating system, applications, or programs can be located in storage devices 916, which are in communication with processor unit 904 through communications fabric 902. The processes of the different embodiments can be performed by processor unit 904 using computer-implemented instructions, which may be located in a memory, such as memory 906.

These instructions are referred to as program instructions, computer usable program instructions, or computer-readable program instructions that can be read and executed by a processor in processor unit 904. The program instructions in the different embodiments can be embodied on different physical or computer-readable storage media, such as memory 906 or persistent storage 908.

Program instructions 918 are located in a functional form on computer- readable media 9 20 that is selectively removable and can be loaded onto or transferred to data processing system 900 for execution by processor unit 904. Program instructions 918 and computer-readable media 9 20 form computer program product 922 in these illustrative examples. In the illustrative example, computer-readable media 9 20 is computer-readable storage media 924.

Computer-readable storage media 924 is a physical or tangible storage device used to store program instructions 918 rather than a medium that propagates or transmits program instructions 918. Computer-readable storage media 924, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Alternatively, program instructions 918 can be transferred to data processing system 900 using a computer-readable signal media. The computer-readable signal media are signals and can be, for example, a propagated data signal containing program instructions 918. For example, the computer-readable signal media can be at least one of an electromagnetic signal, an optical signal, or any other suitable type of signal. These signals can be transmitted over connections, such as wireless connections, optical fiber cable, coaxial cable, a wire, or any other suitable type of connection.

Further, as used herein, “computer-readable media 9 20” can be singular or plural. For example, program instructions 918 can be located in computer-readable media 9 20 in the form of a single storage device or system. In another example, program instructions 918 can be located in computer-readable media 9 20 that is distributed in multiple data processing systems. In other words, some instructions in program instructions 918 can be located in one data processing system while other instructions in program instructions 918 can be located in one data processing system. For example, a portion of program instructions 918 can be located in computer-readable media 9 20 in a server computer while another portion of program instructions 918 can be located in computer-readable media 9 20 located in a set of client computers.

The different components illustrated for data processing system 900 are not meant to provide architectural limitations to the manner in which different embodiments can be implemented. In some illustrative examples, one or more of the components may be incorporated in or otherwise form a portion of another component. For example, memory 906, or portions thereof, may be incorporated in processor unit 904 in some illustrative examples. The different illustrative embodiments can be implemented in a data processing system including components in addition to or in place of those illustrated for data processing system 900. Other components shown in FIG. 9 can be varied from the illustrative examples shown. The different embodiments can be implemented using any hardware device or system capable of running program instructions 918.

Thus, illustrative embodiments of the present disclosure provide a computer-implemented method, computer system, and computer program product for managing containers. The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The description of the different illustrative embodiments has been presented for purposes of illustration and description and is not intended to be exhaustive or limited to the embodiments in the form disclosed. The different illustrative examples describe components that perform actions or operations. In an illustrative embodiment, a component can be configured to perform the action or operation described. For example, the component can have a configuration or design for a structure that provides the component an ability to perform the action or operation that is described in the illustrative examples as being performed by the component. Further, to the extent that terms “includes”, “including”, “has”, “contains”, and variants thereof are used herein, such terms are intended to be inclusive in a manner similar to the term “comprises” as an open transition word without precluding any additional or other elements.

The descriptions of the various embodiments of the present invention have been presented for purposes of illustration but are not intended to be exhaustive or limited to the embodiments disclosed. Not all embodiments will include all of the features described in the illustrative examples. Further, different illustrative embodiments may provide different features as compared to other illustrative embodiments. Many modifications and variations will be apparent to those of ordinary skill in the art without departing from the scope and spirit of the described embodiment. The terminology used herein was chosen to best explain the principles of the embodiment, the practical application or technical improvement over technologies found in the marketplace, or to enable others of ordinary skill in the art to understand the embodiments disclosed here.

What is claimed is:

1. A computer implemented method for generating a compressed dataset, the computer implemented method comprising:
training, by a processor set, a first machine learning model using a dataset, wherein the first machine learning model is trained to generate probabilities of predictions based on a number of features extracted from columns in the dataset;
ranking, by the processor set, the number of features based on a feature attribution analysis for the number of features, wherein the feature attribution analysis determines contribution of each feature from the number of features to predictions made by the first machine learning model; and
expanding, by the processor set, a feature vector using a number of top ranked features from the number of features for generating the compressed dataset, wherein the compressed dataset comprises a number of data entries from the dataset that is associated with the number of top ranked features from the number of features.

2. The computer implemented method of claim 1, wherein expanding, by the processor set, a feature vector to generate the compressed dataset using a number of data entries from the dataset comprises:
selecting, by the processor set, a first top ranked feature from the number of features based on ranking for the number of features, wherein the feature vector is expanded using the top ranked feature;
identifying, by the processor set, a number of rows from the dataset, wherein the number of rows is identified based on column associated with the first top ranked feature; and
merging, by the processor set, the number of rows into single row in the dataset to generate the compressed dataset.

3. The computer implemented method of claim 2, further comprising:
generating, by the processor set, an output using a second machine learning model for solving an optimization problem based on the compressed dataset;
performing, by the processor set, a convergence analysis to determine quality of the compressed dataset based on the output;
determining, by the processor set, whether the quality of the compressed dataset exceeds a pre-defined threshold; and
in response to determining that the quality of the compressed dataset does not exceed the pre-defined threshold, compressing, by the processor set, the compressed dataset by incrementally merging rows in the compressed dataset based on the number of top ranked features until the quality of the compressed dataset exceeds the pre-defined threshold.

4. The computer implemented method of claim 3, further comprising:
inputting, by the processor set, the compressed dataset to the second machine learning model for making a decision to solve an optimization problem.

5. The computer implemented method of claim 3, wherein compressing, by the processor set, the compressed dataset by incrementally merging rows in the compressed dataset based on the number of top ranked features until the quality of the compressed dataset exceeds the pre-defined threshold comprises:
selecting, by the processor set, a second top ranked feature from the number of features based on ranking for the number of features, wherein the feature vector is expanded using the second top ranked feature, wherein the second top ranked feature is ranked immediately after the first top ranked feature;
identifying, by the processor set, a number of second rows from the compressed dataset, wherein the number of second rows is identified based on columns associated with the first top ranked feature and the second top ranked feature; and
merging, by the processor set, the number of second rows into single row in the compressed dataset to update the compressed dataset.

6. The computer implemented method of claim 3, wherein the convergence analysis is performed using Mixed Integer Programming (MIP).

7. The computer implemented method of claim 1, wherein the number of features is ranked using Shapley Additive exPlanations (SHAP) scores associated with the number of features.

8. A computer system for generating a compressed dataset, comprising:
a processor set;
a set of one or more computer-readable storage media; and
program instructions stored on the set of one or more computer-readable storage media to cause the processor set to perform operations comprising:
training a first machine learning model using a dataset, wherein the first machine learning model is trained to generate probabilities of predictions based on a number of features extracted from columns in the dataset;
ranking the number of features based on a feature attribution analysis for the number of features, wherein the feature attribution analysis determines contribution of each feature from the number of features to predictions made by the first machine learning model; and
expanding a feature vector using a number of top ranked features from the number of features for generating the compressed dataset, wherein the compressed dataset comprises a number of data entries from the dataset that is associated with the number of top ranked features from the number of features.

9. The computer system of claim 8, wherein expanding a feature vector to generate the compressed dataset using a number of data entries from the dataset comprises:
selecting a first top ranked feature from the number of features based on ranking for the number of features, wherein the feature vector is expanded using the top ranked feature;
identifying a number of rows from the dataset, wherein the number of rows is identified based on column associated with the first top ranked feature; and
merging the number of rows into single row in the dataset to generate the compressed dataset.

10. The computer system of claim 9, wherein the operations further comprise:
generating an output using a second machine learning model for solving an optimization problem based on the compressed dataset;
performing a convergence analysis to determine quality of the compressed dataset based on the output;
determining whether the quality of the compressed dataset exceeds a pre-defined threshold; and
in response to determining that the quality of the compressed dataset does not exceed the pre-defined threshold, compressing the compressed dataset by incrementally merging rows in the compressed dataset based on the number of top ranked features until the quality of the compressed dataset exceeds the pre-defined threshold.

11. The computer system of claim 10, wherein the operations further comprise:
inputting the compressed dataset to the second machine learning model for making a decision to solve an optimization problem.

12. The computer system of claim 10, wherein compressing the compressed dataset by incrementally merging rows in the compressed dataset based on the number of top ranked features until the quality of the compressed dataset exceeds the pre-defined threshold comprises:
selecting a second top ranked feature from the number of features based on ranking for the number of features, wherein the feature vector is expanded using the second top ranked feature, wherein the second top ranked feature is ranked immediately after the first top ranked feature;
identifying a number of second rows from the compressed dataset, wherein the number of second rows is identified based on columns associated with the first top ranked feature and the second top ranked feature; and
merging the number of second rows into single row in the compressed dataset to update the compressed dataset.

13. The computer system of claim 10, wherein the convergence analysis is performed using Mixed Integer Programming (MIP).

14. The computer system of claim 8, wherein the number of features is ranked using Shapley Additive exPlanations (SHAP) scores associated with the number of features.

15. A computer program product for generating a compressed dataset, comprising:
a set of one or more computer-readable storage media;
program instructions stored in the set of one or more computer-readable storage media to perform operations comprising:
training, by a processor set, a first machine learning model using a dataset, wherein the first machine learning model is trained to generate probabilities of predictions based on a number of features extracted from columns in the dataset;
ranking, by the processor set, the number of features based on a feature attribution analysis for the number of features, wherein the feature attribution analysis determines contribution of each feature from the number of features to predictions made by the first machine learning model; and
expanding, by the processor set, a feature vector using a number of top ranked features from the number of features for generating the compressed dataset, wherein the compressed dataset comprises a number of data entries from the dataset that is associated with the number of top ranked features from the number of features.

16. The computer program product of claim 15, wherein expanding, by the processor set, a feature vector to generate the compressed dataset using a number of data entries from the dataset comprises:
selecting, by the processor set, a first top ranked feature from the number of features based on ranking for the number of features, wherein the feature vector is expanded using the top ranked feature;
identifying, by the processor set, a number of rows from the dataset, wherein the number of rows is identified based on column associated with the first top ranked feature; and
merging, by the processor set, the number of rows into single row in the dataset to generate the compressed dataset.

17. The computer program product of claim 16, wherein the operations further comprise:
generating, by the processor set, an output using a second machine learning model for solving an optimization problem based on the compressed dataset;
performing, by the processor set, a convergence analysis to determine quality of the compressed dataset based on the output;
determining, by the processor set, whether the quality of the compressed dataset exceeds a pre-defined threshold; and
in response to determining that the quality of the compressed dataset does not exceed the pre-defined threshold, compressing, by the processor set, the compressed dataset by incrementally merging rows in the compressed dataset based on the number of top ranked features until the quality of the compressed dataset exceeds the pre-defined threshold.

18. The computer program product of claim 17, wherein the operations further comprise:
inputting, by the processor set, the compressed dataset to the second machine learning model for making a decision to solve an optimization problem.

19. The computer program product of claim 17, wherein compressing, by the processor set, the compressed dataset by incrementally merging rows in the compressed dataset based on the number of top ranked features until the quality of the compressed dataset exceeds the pre-defined threshold comprises:
selecting, by the processor set, a second top ranked feature from the number of features based on ranking for the number of features, wherein the feature vector is expanded using the second top ranked feature, wherein the second top ranked feature is ranked immediately after the first top ranked feature;
identifying, by the processor set, a number of second rows from the compressed dataset, wherein the number of second rows is identified based on columns associated with the first top ranked feature and the second top ranked feature; and
merging, by the processor set, the number of second rows into single row in the compressed dataset to update the compressed dataset.

20. The computer program product of claim 15, wherein the number of features is ranked using Shapley Additive exPlanations (SHAP) scores associated with the number of features.
